(19) United States
(12) Patent Application Publication
(10) Pub. No.: US 2021/0249371 A1
(43) Pub. Date: Aug. 12, 2021

(54) SEMICONDUCTOR DEVICE PACKAGE CONTAINING A MEMS DEVICE AND METHOD FOR MANUFACTURING THE SAME

(71) Applicant: Advanced Semiconductor Engineering, Inc., Kaohsiung (TW)

(72) Inventors: Jia-Zhe LEE, Kaohsiung (TW); Tai-Hung KUO, Kaohsiung (TW)

(73) Assignee: Advanced Semiconductor Engineering, Inc., Kaohsiung (TW)

(21) Appl. No.: 16/786,590

(22) Filed: Feb. 10, 2020

(51) Int. Cl. H01L 23/00; B81C 1/00; B81B 7/02; C09J 183/04; C09J 127/22

(52) U.S. Cl. CPC H01L 24/02; B81C 1/00285; B81B 7/02; C09J 183/04; H01L 2224/05391; B81C 2203/0145; H01L 2924/1461; H01L 2924/163; C09J 127/22

(57) ABSTRACT

A semiconductor device package includes a substrate, a lid, a MEMS device and a gel. The lid is disposed on the substrate and defines a cavity together with the substrate. The MEMS device is disposed in the cavity. The gel covers the MEMS component. The lid is attached to the substrate through a silicone-based adhesive.

### BACKGROUND

### 1. Technical Field

The present disclosure relates to a semiconductor device package containing a MEMS device and a method for manufacturing the same.

### 2. Description of the Related Art

In certain semiconductor devices, such as those including a pressure sensing die enclosed with a lid, it is known to apply a gel over the pressure sensing die to protect the die while still allowing the die to sense the pressure outside the package. The lid is attached to the substrate with the use of lid paste. However, it has been found that bubbles may generate for a period of time, thereby affecting the performance of the device.

### SUMMARY

In some embodiments, the present disclosure provides a semiconductor device package. The semiconductor device package includes a substrate, a lid, a MEMS device and a gel. The lid is disposed on the substrate and defines a cavity together with the substrate. The MEMS device is disposed in the cavity. The gel covers the MEMS component. The lid is attached to the substrate through a silicone-based adhesive.

In some embodiments, a method of manufacturing a semiconductor device package includes the following operations. A substrate is provided. A MEMS device is disposed on the substrate. A lid is disposed on the substrate to enclose the MEMS device and defines, together with the substrate, a cavity for accommodating the MEMS device. The lid is attached to the substrate through a silicone-based adhesive. A gel is filled into the cavity to cover the MEMS device.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a schematic cross-sectional view of a semiconductor device package in accordance with comparative embodiments.

FIG. 2 is a schematic cross-sectional view of a semiconductor device package in accordance with some embodiments of the present disclosure.

FIG. 3A, FIG. 3B, FIG. 3C, FIG. 3D, FIG. 3E and FIG. 3F illustrate operations of manufacturing a semiconductor device package in accordance with some embodiments of the present disclosure.

Common reference numerals are used throughout the drawings and the detailed description to indicate the same or similar components. Embodiments of the present disclosure will be readily understood from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation or disposal of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

MEMS (as used herein, the term “MEMS” may be used to refer to a singular microelectromechanical system or to a plurality of microelectromechanical systems) can be used in semiconductor devices to detect a signal (such as sound, movement or motion, pressure, gas, humidity, temperature, and the like) and to transform the detected signal to an electrical signal.

The present disclosure describes techniques suitable for the manufacture of a semiconductor device package including a MEMS device which uses silicone-based adhesive as the lid paste. As compared to the use of the lid paste containing an epoxy-based polymer, the semiconductor device package according to the present disclosure does not generate bubbles even after a long period of time.

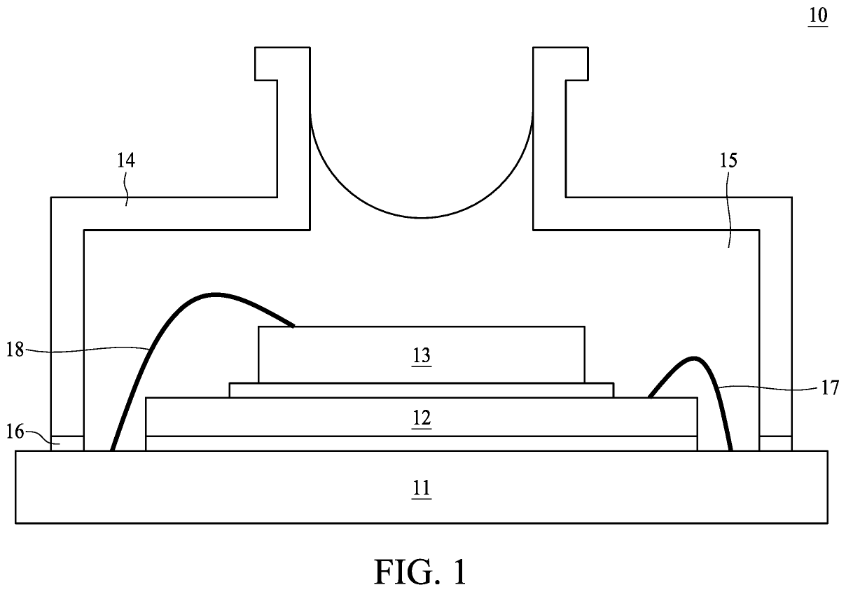

FIG. 1 is a schematic cross-sectional view of a semiconductor device package 10 in accordance with some embodiments of the present disclosure. The semiconductor device package 10 includes a substrate 11, a lid 14, a MEMS device 13, a gel 15 and a silicone-based adhesive 16.

The substrate 11 may include, a ceramic substrate, an organic substrate or a leadframe. The substrate 11 may include an electrical connection structure, such as pads, traces or vias. The lid 14 (e.g. a housing) is disposed on the substrate 11 and defines a cavity together with the substrate 11 to accommodate one or more electronic devices. The lid 14 may have an opening to communicate the cavity with the external environment or expose the MEMS device 13. In some embodiments, the opening may locate, for example, on a top of the lid 14 as shown in FIG. 1. As shown in FIG. 1, the lid may have a protrusion at a top and the sidewall of the protrusion defines the opening. In some embodiments, the lid 14 may include a conductive thin film or a metal layer (e.g., a metal lid), and may include, for example, aluminum, copper, chromium, tin, gold, silver, nickel or stainless steel, or a mixture, an alloy, or other combination thereof. In some embodiments, the lid 14 is a metal lid.

The semiconductor device package 10 may includes one or more electronic devices (e.g., The MEMS device 13 and a second electronic device 12) disposed on includes a top surface of the substrate 11 and in the cavity defined by the substrate 11 and the lid 14. The MEMS device 13 may be or include, for example, a pressure sensor, a microphone or a gyroscope. In some embodiments, the second electronic device may be or include, for example, an application-specific integrated circuit (ASIC) die, a controller, a processor, a memory, or other electronic component or semiconductor device. The electronic devices 12 and 13 may be disposed side-by-side or stacked on each other. The electronic devices 12 and 13 may be electrically connected to each other or electrically connected to the substrate 11.

In the embodiments shown in FIG. 1, the MEMS device 13 is stacked on the electronic device 12 (e.g., an ASIC die). The MEMS device 13 is electrically connected to the substrate 11, e.g., by a wire 18. The electronic device 12 is electrically connected to the substrate 11, e.g., by a wire 17. The gel 15 fills the cavity and covers the MEMS device 13 and the electronic device 12. The gel 15 allows gas (or air) penetration but prevents from moisture penetration.

In some embodiments, the gel may be or include a polymer containing silicone groups. In some embodiments, the gel may be or include a polymer terminated with silicone group. In some embodiments, the gel may be or include a perfluoropolyether terminated with silicone groups. The perfluoropolyether may have a backbone containing a plurality of —CₐF₂ₐO— repeating units where a in each unit is independently an integer from 1 to 6 (i.e., 1, 2, 3, 4, 5 or 6). In some embodiments, the repeating unit —CₐF₂ₐO— includes —CF₂O—, —CF₂CF₂O—, —CF₂CF₂CF₂O—, —CF₂CF(CF₃)O—, —CF₂CF₂CF₂CF₂O—, —CF₂CF₂CF₂CF₂CF₂CF₂O—, or —C(CF₃)₂O—, of which CF₂CF(CF₃)O— is preferred. In some embodiments, the gel 15 may be, for example, but is not limited to: those manufactured by Dow Corning under the trademark name of Fluorogel, such as Fluorogel™ 4-8022 or those manufactured by ShinEtsu under the trademark name of SIFEL, such as SIFEL8070-A/B or SIFEL8470.

In some embodiments, the gel 15 not include a polymer containing an epoxy group.

The lid 14 is attached to the substrate 11 through a silicone-based adhesive 16. In some embodiments, the silicone-based adhesive includes: (a) an organopolysiloxane having aliphatic unsaturation; (b) an organopolysiloxane crosslinker including a silicon atom-bonded hydrogen atom; and (c) hydrosilylation catalyst.

Component (a) is an organopolysiloxane having aliphatic unsaturation. In some embodiments, besides the aliphatic unsaturation, the component (a) includes a plurality of repeating units having the following formula:

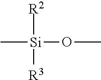

where R² and R³ in each repeating unit may be the same or different and are independently selected from C₁₋₃ alkyl (e.g., methyl, ethyl or propyl) and aryl (e.g., phenyl). The organopolysiloxane of component (a) includes one or more aliphatic unsaturated hydrocarbon groups, preferably two or more aliphatic unsaturated hydrocarbon groups, per molecule. In some embodiments, component (a) includes from 2 to 100 aliphatic unsaturated hydrocarbon groups per molecule, e.g., 2, 5, 10, 20, 50, 60, 80, 90 or 100 aliphatic unsaturated hydrocarbon groups per molecule. The aliphatic unsaturated hydrocarbon groups may be alkenyl groups having 2 to 8 carbon atoms, preferably, 2 to 6 carbon atoms. Examples of the alkenyl groups include vinyl, allyl, propenyl, isopropenyl, butenyl, hexenyl, heptenyl, cyclohexenyl and octenyl. The aliphatic unsaturated hydrocarbon groups may be bonded either to silicon atoms at the ends of the molecular chain or to silicon atoms at the pending groups.

Component (b) is an organopolysiloxane having a silicon atom-bonded hydrogen atom and may act as a chain extender or a crosslinker. In some embodiments, besides the silicon atom-bonded hydrogen atom, the component (b) includes a plurality of repeating units having the following formula:

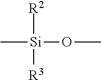

where R² and R³ in each repeating unit may be the same or different and are independently selected from C₁₋₃ alkyl (e.g., methyl, ethyl or propyl) and aryl (e.g., phenyl). The organopolysiloxane of component (b) include one or more silicon-bonded hydrogen atoms (—SiH groups), preferably two or more silicon-bonded hydrogen atoms, per molecule. In some embodiments, component (b) includes 2 to 100 silicon-bonded hydrogen atoms, e.g., 2, 5, 10, 20, 50, 60, 80, 90 or 100 silicon-bonded hydrogen atoms, per molecule.

Compound (c) is a hydrosilylation catalyst. The hydrosilylation catalysts are known in the art, which include, but is not limited to, platinum-based catalysts, palladium-based catalysts, rhodium-based catalysts, ruthenium-based catalysts, osmium-based catalysts and iridium-based catalysts.

Component (b) is capable of undergoing an addition reaction (e.g., hydrosilylation) with component (a). In the presence of compound (c) and under suitable conditions (e.g., with UV irradiation or heat applied), the —SiH groups of component (b) react with the aliphatic unsaturated hydrocarbon groups of component (a). Component (b) may be present in an amount that the molar ratio of the —SiH groups of component (b) and the aliphatic unsaturated hydrocarbon groups of component (a) is ranging from 0.5 to 5, e.g., 0.5, 0.8, 1, 1.2, 1.5, 1.8, 2, 3, 4 or 5.

In some embodiments, the silicone-based adhesive 16 may include electrically-conductive fillers. In some embodiments, the electrically-conductive fillers are metal particles, e.g., Ag.

In some embodiments, the silicone-based adhesive 16 not include a polymer containing an epoxy group.

In some embodiments, the silicone-based adhesive 16 may be, for example, but is not limited to: those manufactured by Dow Corning under the trademark name of DA6501, DA6503, EA-6247, 3-6265, EA-6700, DA6523, DA6524, DA6534 or ME1800.

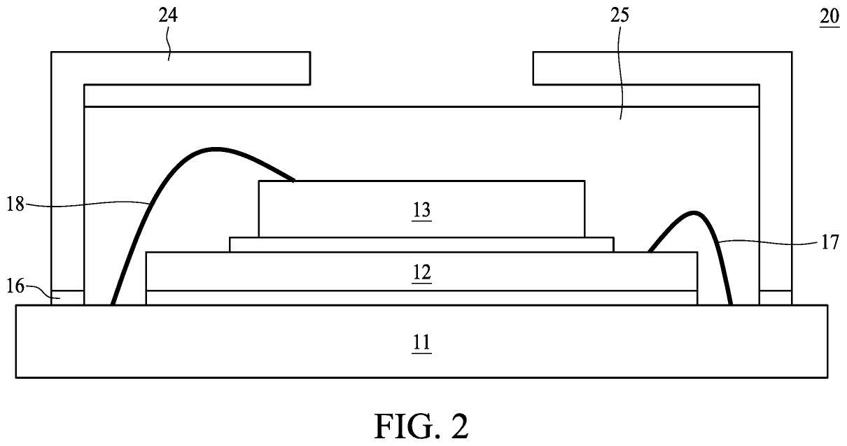

FIG. 2 is a schematic cross-sectional view of a semiconductor device package 20 in accordance with some embodiments of the present disclosure. Similar to the semiconductor device package 20 has a structure similar to the semiconductor device package 10 illustrated in FIG. 1, except that the lid 24 has a flat top surface and the height of the gel 25. The gel 25 fills in the cavity and covers the MEMS device 13 and the electronic device 12. The gel 25 may fully fill the cavity in some embodiments, or partially fills the cavity as shown in FIG. 2

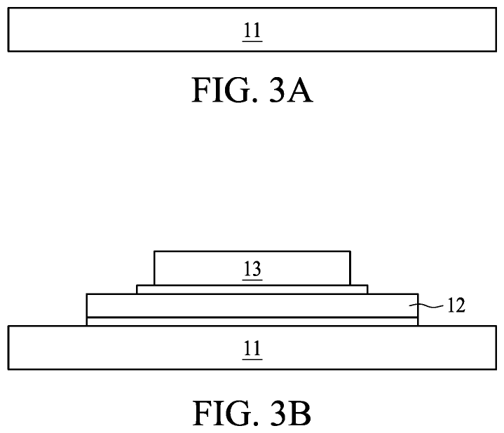

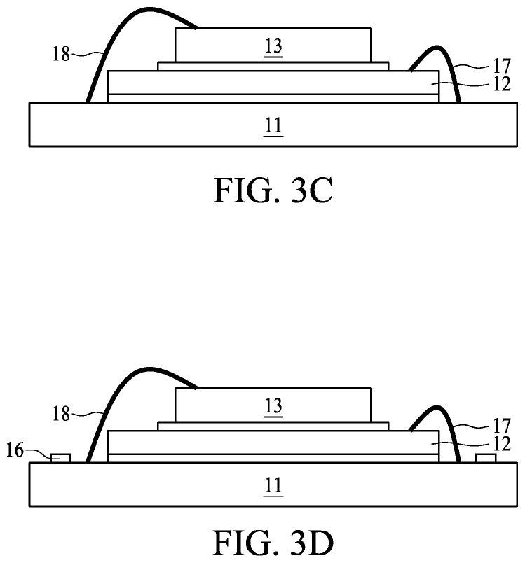

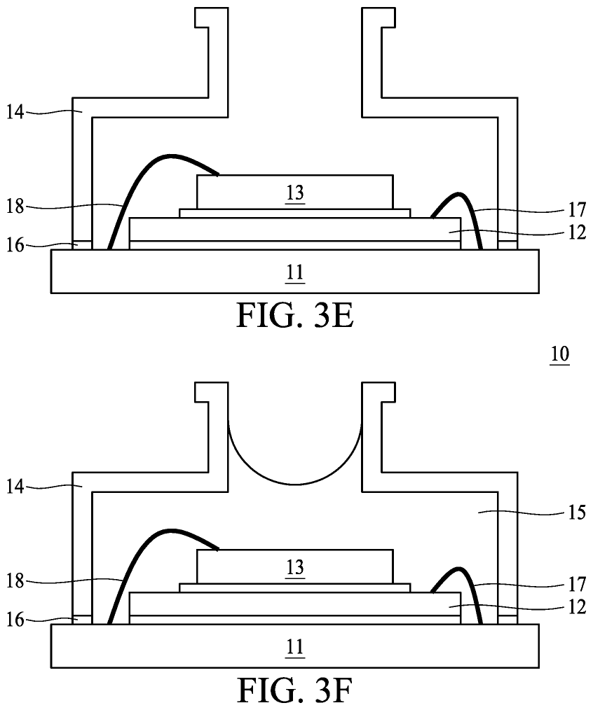

FIG. 3A, FIG. 3B, FIG. 3C, FIG. 3D, FIG. 3E and FIG. 3F illustrate operations of manufacturing a semiconductor device package in accordance with some embodiments of the present disclosure.

Referring to FIG. 3A, a substrate 11 is provided.

Referring to FIG. 3B, an electronic device 12 (e.g., an ASIC die) is disposed on a top surface of the substrate 11 and then a MEMS device 13 is stacked on the electronic device 12. In some embodiments, an adhesive (e.g., a die attach film (DAF)) may be disposed between the top surface of the substrate 11 or between the electronic device 12 and the MEMS device 13.

Referring to FIG. 3C, the MEMS device 13 is electrically connected to the substrate 11 via a wire 18 and the electronic device 12 is electrically connected to the substrate 11 via a wire 17.

Referring to FIG. 3D, a silicone-based adhesive 16 is applied onto the top surface of the substrate 11 and baked at an elevated temperature (e.g., 100° C. or above) for a period of time (e.g., 30 mins or more) to remove the solvent and cure the silicone-based adhesive. The baking temperature may be 100° C., 120° C., 150° C., 180° C., 200° C., 230° C., 250° C. or above. The baking time may be 30 mins, 50 mins, 60 mins, 80 mins, 100 mins, 120 mins, 150 mins or 180 mins.

Referring to FIG. 3E, a lid 14 is disposed on the top surface of the substrate 11. A bottom surface of the lid 14 is bonded to the top surface of the substrate 11 by the silicone-based adhesive 16. In some embodiments, the silicone-based adhesive 16 covers the whole bottom surface of the substrate 11. The lid 14 encloses the MEMS device 13, the electronic device 12 and the wires 17 and 18. The lid 14 has a protrusion at a top of the lid and the sidewall of the protrusion defines an opening to expose the MEMS device 13 to the external environment. The lid 14 defines a cavity together with the substrate 11.

Referring to FIG. 3F, a gel 15 fills into the cavity defined by the lid 14 and the substrate 11 to prepare the semiconductor device package 10. The gel covers the MEMS device 13, the electronic device 12 and the wires 17 and 18. After gel filling, the semiconductor device package 10 is sent to a vacuum (or a vacuum-like) chamber for a period of time to remove gas from the gel 15 (i.e., a degassing operation). Finally, a heating operation is carried out at an elevated temperature (e.g., 60° C. or above) for a period of time (e.g., 30 mins or more) to remove the solvent in the gel and cure the gel. The heating temperature may be 100° C., 120° C., 150° C., 180° C., 200° C., 230° C., 250° C. or above. The heating time may be 30 mins, 50 mins, 60 mins, 80 mins, 100 mins, 120 mins, 150 mins or 180 mins. In some embodiments, the heating is carried out at a vacuum chamber so that the degassing operation and the heating operation can be carried out simultaneously.

EXAMPLES

Some embodiments of the present disclosure will now be further explained with reference to the following working examples and comparative examples; however, these examples do not restrict the scope of embodiments of this disclosure.

In the working examples and comparative examples, a semiconductor device package including a substrate 11, a MEMS device 13, and an ASIC die 12 is prepared in accordance with the operations illustrated by FIGS. 3A to 3C. CE3920 manufactured by Henkel, 84-1LMIS24 manufactured by Henkel and DA-6534 manufactured by Dow Corning are respectively used as an adhesive 16 (i.e., lid paste) to adhere a lid 14 to the substrate in accordance with the operations illustrated by FIGS. 3D and 3E. The baking temperature and time are illustrated in Table 1 (note: the baking temperature and time are for the purpose of curing the adhesive and thus can be adjusted as needed). Then, SIFEL8070-A/B manufactured by ShinEtsu is used as a gel 15 to fill into the cavity defined by the lid and the substrate. After gel filling, the semiconductor device package 10 is sent to a vacuum chamber for an hour and then heated at 60° C. for 30 mins and at 150° C. for an hour for curing.

The 1^{st} Observation regarding whether there are bubbles retained in the gel is carried out after gel curing. Then, the semiconductor device package is subjected to an 85° C./85RH reliability test for 16 hours. The 2_{nd} Observation regarding whether there are bubbles retained in the gel is carried out after the reliability test. The 3^{rd} after Observation regarding whether there are bubbles retained in the gel is carried out after 15 hours (the semiconductor device package is kept at room temperature) from the 2^{nd} Observation.

The results of bubble observation are recorded in Table 1.

TABLE 1

| | Compar. Ex 1 | Compar. Ex 2 | Compar. Ex 3 | Compar. Ex 4 | Ex 1 |
|---|---|---|---|---|---|
| Lid paste | CE3920 | CE3920 | 84-1LMIS24 | 84-1LMIS24 | DA-6534 |
| Baking | 150° C./60 min | 150° C./180 min | 175° C./60 min | 175° C./180 min | 150° C./60 min |
| 1^{st} | No bubbles | No bubbles | No bubbles | No bubbles | No bubbles |
| Observation | | | | | |
| 2^{nd} | Bubbles | Bubbles | Bubbles | Bubbles | No bubbles |
| Observation | observed | observed | observed | observed | |
| 3^{rd} | Bubbles | Bubbles | No bubbles | No bubbles | No bubbles |
| Observation | observed | observed | | | |

CE3920 is used as lid paste in Comparative Examples 1 and 2. 84-1LMIS24 is used as lid paste in Comparative Examples 3 and 4. CE3920 and 84-1LMIS24 both contain an epoxy-based polymer. In Comparative Examples 1, 2, 3 and 4, no bubbles are observed after gel curing but bubbles occur after the reliability test.

The bubbles may be resulted from the reaction of the epoxy groups of the lid paste with the silicone groups of the gel. During the manufacture of the semiconductor device package, most of solvents are removed by heating/curing while a complicated polymeric structure (e.g., a crosslinked structure) is formed at the same time. The epoxy groups from the lid paste may react with the silicone groups from the gel at the interface of the gel and the lid paste during or after gel curing. The ring-opening reaction of the epoxy groups results in many —OH groups pending at the polymeric chain. The by-product (i.e., water) of the ring opening may be trapped by the polymeric structure and may form a hydrogen bonding with the —OH groups in the polymeric structure, and therefore, it is difficult to completely remove water during heating/curing. The residual water slowly releases from the interface and passes through the gel to the external and thus bubbles generate. The bubbles may diffuse from the gel into the external after a long time. However, the presence of bubbles within the gel already affects the appearance and performance of the semiconductor device package and it is difficult to predict whether and when the bubbles can be totally removed or whether no new bubbles will generate.

DA-6534 is used as lid paste in Example 1. DA-6534 is a silicone-based adhesive. A silicone-based adhesive, such as DA-6534, has good compatibility with the gel. As shown in Table 1, no bubbles are observed after gel curing, after 85° C./85RH reliability test or even after 15 hours storage after the reliability test. This may because that the silicone-based adhesive does not react with the gel to generate water. Even if water may generate, the silicone-based adhesive does not contain sufficient —OH groups as an epoxy-based polymer subjected to ring-opening reaction, water is weakly bonded with the polymeric structure via van del waals force and can be easily removed during heating/curing.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor device package, comprising:
a substrate;
a lid disposed on the substrate and defining a cavity together with the substrate;
a MEMS device disposed in the cavity; and
a gel covering the MEMS component,
wherein the lid is attached to the substrate through a silicone-based adhesive.

2. The semiconductor device package of claim 1, wherein the gel is a polymer containing silicone groups.

3. The semiconductor device package of claim 1, wherein the gel is a polymer terminated with silicone groups.

4. The semiconductor device package of claim 1, wherein the gel is a perfluoropolyether polymer terminated with silicone groups.

5. The semiconductor device package of claim 4, wherein the perfluoropolyether polymer has a backbone containing a plurality of —CₐF₂ₐO— repeating units where a in each unit is independently an integer from 1 to 6.

6. The semiconductor device package of claim 1, wherein the silicone-based adhesive comprises electrically-conductive fillers.

7. The semiconductor device package of claim 1, wherein the silicone-based adhesive comprises (a) an organopolysiloxane having aliphatic unsaturation; (b) an organopolysiloxane having a silicon atom-bonded hydrogen atom; and (c) hydrosilylation catalyst.

8. The semiconductor device package of claim 7, wherein (a) the organopolysiloxane comprises a plurality of repeating units having the following formula: 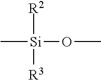
where R² and R³ in each repeating unit may be the same or different and are independently selected from C₁₋₃ alkyl and aryl.

9. The semiconductor device package of claim 7, wherein (b) the organopolysiloxane having a silicon atom-bonded hydrogen atom comprises a plurality of repeating units having the following formula: 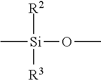
where R² and R³ in each repeating unit may be the same or different and are independently selected from C₁₋₃ alkyl and aryl.

10. The semiconductor device package of claim 1, wherein the silicone-based adhesive comprises those manufactured by Dow Corning under the trademark name of DA-6534.

11. The semiconductor device package of claim 1, wherein the lid defines an opening exposing the MEMS device.

12. The semiconductor device package of claim 1, further comprising a semiconductor device (15) disposed in the cavity.

13. The semiconductor device package of claim 11, wherein the MEMS device and the semiconductor device are disposed on a top surface of the substrate side-by-side.

14. The semiconductor device package of claim 11, wherein the semiconductor device is disposed on a top surface of the substrate and the MEMS device is stacked on the semiconductor device.

15. The semiconductor device package of claim 11, wherein the semiconductor device is electrically connected to the substrate.

16. The semiconductor device package of claim 11, wherein the MEMS device is electrically connected to the substrate.

17. A method of manufacturing a semiconductor device package, comprising:
providing a substrate;
disposing a MEMS device on the substrate;
disposing a lid on the substrate to enclose the MEMS device, wherein the lid and the substrate define a cavity for accommodating the MEMS device and the lid is attached to the substrate through a silicone-based adhesive; and
filling a gel into the cavity to cover the MEMS device.

18. The method of claim 17, wherein the disposing a lid on the substrate to enclose the MEMS device comprises:
applying a silicone-based adhesive on the substrate;
heating the silicone-based adhesive; and
disposing the lid on the silicone-based adhesive.

19. The method of claim 17, further comprising heating semiconductor device package after filling the gel.

20. The method of claim 19, wherein the heating is carried out at a vacuum chamber.
